(19) United States
(12) Patent Application Publication
(10) Pub. No.: US 2022/0069824 A1
(43) Pub. Date: Mar. 3, 2022

(54) CASCADABLE MEMS LOGIC DEVICE BASED ON MODES ACTIVATION

(71) Applicant: KING ABDULLAH UNIVERSITY OF SCIENCE AND TECHNOLOGY, Thuwal (SA)

(72) Inventors: Sherif Adekunle TELLA, Thuwal (SA); Mohammad Ibrahim YOUNIS, Thuwal (SA)

(21) Appl. No.: 17/411,698

(22) Filed: Aug. 25, 2021

Related U.S. Application Data
(60) Provisional application No. 63/072,367, filed on Aug. 31, 2020.

(51) Int. Cl. H03K 19/21; B81B 3/00

(52) U.S. Cl. CPC H03K 19/21; B81B 3/0086; B81B 2203/0109; B81B 2203/04; B81B 2201/0271

(57) ABSTRACT

A cascadable resonator logic system includes a substrate; a first straight beam anchored with a first end to the substrate; a second straight beam anchored with a first end to the substrate; a first arch beam, which is curved, and is attached with a first end to a second end of the first straight beam, at a first joint, and with a second end to a second end of the second straight beam, at a second joint, so that both the first and second ends of the first arch beam are suspended above the substrate; and a second arch beam, which is also curved, and is attached with a first end to the second joint, and a second end is anchored to the substrate.

### CROSS-REFERENCE TO RELATED APPLICATION

This application claims priority to U.S. Provisional Patent Application No. 63/072,367, filed on Aug. 31, 2020, entitled “TOWARD CASCADABLE MEMS LOGIC DEVICE BASED ON MODES ACTIVATION,” the disclosure of which is incorporated herein by reference in its entirety.

### BACKGROUND

### Technical Field

Embodiments of the subject matter disclosed herein generally relate to a system and method for providing complex logic functions based on microelectromechanical systems (MEMS), and more particularly, to a cascade of MEMS resonator-based computing devices that use selective modes activation for each logic function so that multi-inputs and multi-outputs complex logic functions can be achieved.

### Discussion of the Background

MEMS resonators have been considerably investigated due to their compatibility with electronic systems and useful capability in different applications, such as sensors, actuators, switches, filters, micro-relays, memory elements and logic gates. Due to the increasing demand for smarter solutions and embedded systems, MEMS resonator-based computing devices have been under considerable attention for their simplicity and prospect of low computational power. A practical MEMS logic device can be achievable through a single conceptual framework that comprises different functional elements such as memory elements and complex logic circuits [1]. However, this conceptual design demands that the outputs of a functional element are applied as inputs into another, which leads to cascadable MEMS resonator-based devices.

In the past few years, considerable publications have investigated the exploitation of MEMS resonators as digital computing devices. Several fundamental logic gates and memory elements have been reported using different behavioral phenomena, such as parametric excitation, multimode excitation [2], and linear and nonlinear frequency modulations [3]. A low actuation voltage and high isolation RF MEMS switches were investigated in [4] by controlling the axial stresses in microbeams to induce desirable buckling and bending effects. A reconfigurable fundamental logic and a random-access memory were demonstrated in [5] based on the induced axial stress from a clamped-guided arch resonator. The modulations of the linear frequency responses were used to illustrate the basic logic gates, while the nonlinear frequency responses were used to demonstrate the random-access memory. Also, [6] reported the use of nonlinear dynamics to describe a multifunctional logic-memory device from a single MEMS resonator integrated with a closed loop control.

There have been successful demonstrations of fundamental logic gates using different MEMS behavioral phenomena. However, these examples only provide a capability of one output at a time, which does not allow the implementation of multi-inputs and multi-outputs complex logic functions within the same device.

Thus, there is a need for a new system that is capable of using MEMS structures that have multi-inputs and are capable of generating multi-outputs complex logic functions.

### BRIEF SUMMARY OF THE INVENTION

According to an embodiment, there is a cascadable resonator logic system that includes a substrate, a first straight beam anchored with a first end to the substrate, a second straight beam anchored with a first end to the substrate, a first arch beam, which is curved, and is attached with a first end to a second end of the first straight beam, at a first joint, and with a second end to a second end of the second straight beam, at a second joint, so that both the first and second ends of the first arch beam are suspended above the substrate, and a second arch beam, which is also curved, and is attached with a first end to the second joint, and a second end is anchored to the substrate.

According to another embodiment, there is a method for performing a logical operation with a cascadable resonator logic system that includes first and second straight beams and first and second arch beams. The method includes applying a first input voltage to a first driving electrode, to bend the second straight beam, wherein a first end of the straight beam is anchored to a substrate and a second end is attached to ends of the first and second arch beams, flexing the first and second arch beams, which are floating above the substrate, except for an end of the second arch beam, to generate a first excitation mode, which is characterized by a first frequency, recording a first output (O1) of the first excitation mode, applying a second input voltage to a second driving electrode, to bend the second straight beam, wherein the first and second driving electrodes sandwich the second straight beam, flexing the first and second arch beams to generate a second excitation mode, which is characterized by a second frequency, which is different from the first frequency, and recording a second output (O2) of the second excitation mode, which is different from the first output (O1). The cascadable resonator logic system works as (1) a half adder logic when both outputs are used, (2) as a XOR logic gate when only the first output is used, and (3) as an AND logic gate when only the second output is used.

### BRIEF DESCRIPTION OF THE DRAWINGS

For a more complete understanding of the present invention, reference is now made to the following descriptions taken in conjunction with the accompanying drawings, in which:

FIG. 1 is a schematic diagram of a cascadable resonator logic system that includes two straight beams and two arch beams connected to each other to form F-shaped coupled resonators;

FIG. 2 illustrates the various dimensions of the two straight beams and two arch beams of the F-shaped coupled resonators;

FIG. 3A illustrates a first mode generated by the F-shaped coupled resonators and FIG. 3B illustrates a second mode generated by the F-shaped coupled resonators;

FIG. 4 illustrates a frequency response of the F-shaped coupled resonators when excited;

FIG. 5 illustrates a phase response of the F-shaped coupled resonators when excited;

FIG. 6 schematically illustrates a half adder logical function achieved by the F-shaped coupled resonators;

FIG. 7 illustrates the inputs and outputs corresponding to the half adder logical function of the F-shaped coupled resonators;

FIG. 8 illustrates the frequency response from S₂₁ measurements of the F-shaped coupled resonators for the half adder logical function;

FIGS. 9A and 9B schematically illustrate an AND gate and an XOR gate logical functions also achieved by the F-shaped coupled resonators;

FIG. 10A illustrates the inputs and outputs corresponding to the XOR gate logical function and FIG. 10B illustrates the inputs and outputs corresponding to the AND gate logical function achieved by the F-shaped coupled resonators;

FIG. 11A illustrates the frequency response from S₂₁ measurements for the XOR gate logic function and FIG. 11B illustrates the frequency response from S₂₁ measurements for the AND gate logic function when using the same F-shaped coupled resonators;

FIGS. 12A and 12B illustrate simulations of the time responses of the first output and second output, respectively, for the F-shaped coupled resonators;

FIG. 13 is a schematic diagram of a cascadable resonator logic system that includes two straight beams and three arch beams connected to each other to form fork-shaped coupled resonators;

FIG. 14 illustrates the various dimensions of the two straight beams and three arch beams;

FIGS. 15A to 15C illustrate the three modes achieved by the fork-shaped coupled resonators;

FIGS. 16A to 16D show the outputs generated by the fork-shaped coupled resonators when various combinations of the inputs are used; and

FIG. 17 is a flow chart of a method for performing one or more logical functions with a same F-shaped coupled resonators.

### DETAILED DESCRIPTION OF THE INVENTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to an F-shape coupled microstructure. However, the embodiments to be discussed next are not limited to such a shape, but may be applied to other shapes of coupled microstructures.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, a novel MEMS based system capable of multi-input, multi-output logical functions uses in-plane, plural microbeams connected to each other, in the form of an F-shape coupled microstructure. The MEMS system includes driving electrodes that supply the multi-input signals and sensing electrodes that supply the multi-output signals. Various resonances of the F-shaped coupled microstructure are exciting for generating the plural logical functions.

In structural dynamics, the presence of disturbances or irregularities in coupled structures may induce the propagation of vibrations in the design. Depending on the order of magnitude of the perturbations and the strength of the internal coupling of the system, the irregularities can localize or delocalize the mode of vibration and hence, confine the vibrational energy to a specific vibration mode such that the amplitude of that mode is higher than the others.

Despite successful demonstrations of basic and complex logic gates, the operating principles of most of these techniques are based on actuating a MEMS resonator near its fundamental natural frequency and then modulate this resonant frequency to the required operating frequency of the device. The frequency modulations are based on applying additional electrostatic or electrothermal DC voltages to the structure. However, these modes of operation drain a substantial amount of power because of the continuous excitation of the resonator at resonance and also due to the additional required DC voltages for the frequency modulations. Furthermore, the cascadability of MEMS resonator-based logic devices is limited by these modes of operation because the logic inputs are based on electrostatic or electrothermal DC voltages. In contrast, the logic outputs are AC motional currents.

On the other hand, the cascadability of MEMS resonators requires that the mode of signals for both logic inputs and outputs be the same, and at the same frequency [7]. This requires signal conditioning circuits, which consist of buffers to prevent distortion of the source signals, parasitic signal removing elements, to get rid of the parasitic signals, and amplifiers for amplifying the output signals of one resonator as input into the next resonator. Note that the approach taken in the following embodiments is compatible with the adiabatic CMOS approach and both CMOS and NEMS can be integrated together to harness the advantages of both concepts.

In the following embodiments, the realization of a cascadable and energy-efficient system that achieves a complex combinational logic function is discussed. For example, in one embodiment, a complex logic function (half-adder) and fundamental logic gates (XOR and AND) are implemented in a single MEMS device, based on selective modes activation. The system uses modes activation and deactivation to propagate the localization and delocalization of multi-vibrational modes of the F-shape coupled resonators. The novel system requires power for actuation only, and this results in significant improvement in energy efficiency because it does not require DC-based frequency modulations. Additionally, the proposed system provides the basis for a cascadable MEMs resonator logic device as it enables both the logic inputs and outputs to be of the same AC signal mode at the same frequency. The structure of such a system is now discussed with regard to the figures.

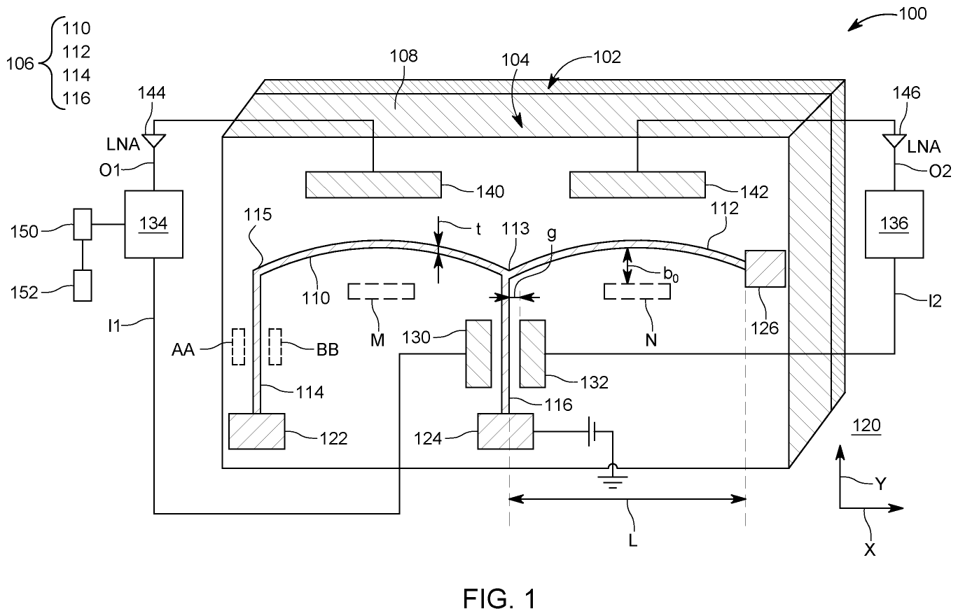

FIG. 1 shows a first possible implementation of the cascadable MEMS resonator logic system 100, simply called cascadable MEMS system or MEMS system herein. The cascadable MEMS system 100 includes, in this embodiment, two arch beams 110 and 112, connected to each other at a common point or joint 113, and two straight beams 114 and 116. The first straight beam 114 is connected with one of its ends to an end of the first arch beam 110, at a common point or joint 115, while the second straight beam 116 is connected with one of its ends to the common point 113, i.e., to an end of each of the arch beams 110 and 112. These specific connections of the arch and straight beams shown in FIG. 1 form the F-shaped coupled microstructure or resonators 106 of the cascadable MEMS system 100. The four beams 110 to 116 are shaped in this embodiment to extend in the same plane 120, which is defined by the X and Y axes in the figure. However, in a different embodiment, the four beams may be positioned to not extend in the same plane, for example, the straight beams may extend into a first plane and the arch beams may extend into a second plane, which is perpendicular to the first plane.

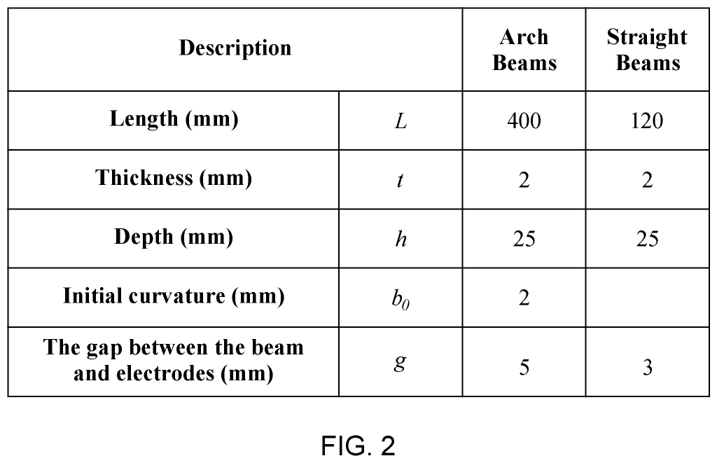

The two straight beams 114 and 116 are straight lines, while the two arch beams 110 and 112 form an arch, each having a corresponding radius. In one application, the first and second arch beams have the same radius of curvature. In another application, the two arch beams can have different radii of curvature. The radius of curvature can extend in the XY plane, or in a plane perpendicular to the XY plane. The dimensions of the straight and arch beams are illustrated in the table in FIG. 2 for this embodiment. Those skilled in the art would understand that other dimensions may be used, that do not deviate by more than 30% of those listed in the table, as long as the dimensions are in the micro-meter ranges. The two arch beams and the two straight beams connected to each other as shown in FIG. 1 form the coupled resonant microstructure 106, which forms the mode generation part of the system 100.

The four beams have only three fixed points or anchors 122, 124, and 126 that are attached to a substrate 102, and all other parts of the beams are suspended above the substrate 102, with a given distance, so that these parts of the beams are free to flex and bend and move relative to the substrate 102. This means that any of the four beams can be deformed by the application of a current, DC or AC. This also means that the coupled resonant microstructure 106 has only three points of contact with the substrate 102, and all other parts of the microstructure are suspended above the substrate. A chamber 104 may be formed around the microstructure 106, by placing a housing 108 onto the substrate 102, around the microstructure 106. In one application, the housing 108 seals the microstructure 106 so that the chamber 104 can be vacuumed.

Two driving electrodes 130 and 132 are placed to sandwich the straight beam 116, the one that connects to the joint 113, between the arch beams 110 and 112. Each of these two driving electrodes are connected to a corresponding analyzer device 134 and 136, respectively. In one embodiment, the analyzer device 134 and/or 136 may be a network analyzer, or any other device that can apply a desired voltage to the corresponding driving electrode. The voltage may be DC or AC voltage. In one application, both driving electrodes are connected to a single network analyzer.

The other end of each analyzer is connected to a corresponding sensing electrode 140 or 142. In one application, both sensing electrodes are connected to the other end of the single analyzer. The sensing electrodes may be located on the substrate 102, as the driving electrodes are. The sensing electrodes are placed to face the middle of the arch beams, to detect a bending (or a frequency of the oscillating beams) of the arch beams. Note that the bending of the arch beams 110 and 112 may take place along either the position or negative directions of the axis Y while the deformation of the straight beam 116 is along the positive or negative directions of the X axis. The other straight beam 114 may also get deformed along the X axis, because of the deformation experienced by the straight beam 116. In other words, by applying desired voltages to one or both of the driving electrodes 130 and 132, the second straight beam 116 is bent along the X axis, which induces the arch beams to flex and the straight beams to deform according to various modes, as will be discussed later.

A controller 150 may be connected to the network analyzers, to control the type of signal being applied to the driving electrodes, which driving electrode to be activated, an amplitude of the applied signal, a timing of applying the signal, and also for analyzing the sensed signal. A power supply 152 may also be provided to the system 100 to supply the electrical power necessary for generating the signals and processing them. In this way, the system 100 may become a self-standing system so that it can perform mathematical operations as required. The controller may be a traditional controller, based on transistors, or a MEMS-based controller.

The system 100 may be fabricated, in one embodiment, by MEMSCAP [8] using a two-mask lithography process. The fabrication process is built on a wafer with a highly conductive phosphorus dopant, on the top surface of the Silicon-On-Insulator wafer using the SOIMUMPs method, which is a four mask level SOI patterning and etching process. The silicon layer has a 25 μm thickness, which is patterned and etched down to the oxide layer to form the depth of the microbeams. The designed F-shaped microstructure includes the two straight and two arch in-plane microbeams that are connected to form the single MEMS resonator system 100. The two straight beams are fixed at one end, and the tips of the other ends are connected to the two arch beams to guide and control their motions. The straight and arch beams may all be sandwiched between pairs of electrodes that serve, in one embodiment, as upper and lower electrodes for each of the straight and arch beams, and these electrodes can be used for electrostatic actuation and sensing of the device. Note that any of the lower electrodes can be used to electrostatically excite the vibrational modes of the resonator, i.e., any of the lower electrodes can be used as the driving electrodes. The outputs can be sensed from any of the upper electrodes.

The driving electrodes are used to electrostatically excite the coupled resonators near their first and second natural frequencies. The excitation is based on the superposition of an in-built AC signal from the network analyzer 134 and/or 136 with a DC voltage applied from a DC supply. Note that no electrothermal process is involved in activating the modes of the structure 106. The network analyzers 134 and 136 provide the input signals I1 and I2 to the driving electrodes 130 and 132, respectively. The excited vibrations induce AC motional currents in the sense electrodes 140 and/or 142, which are amplified by corresponding low noise preamplifiers (LNP) 144 and 146, respectively.

The amplified outputs O1 and O2 from the LNA 144 and 146 are transferred to the input port of the network analyzers 134 and 136, respectively, for S₂₁ transmission measurements. In one application, the parameter specifications for the demonstration of the logic functions are as follows: 20V DC bias, −20 dbm (22.361 mVrms) AC signals, 1 Torr vacuum pressure for the chamber 104 in which the straight and arch beams are kept, at room temperature. For various measurements that were performed by the inventors for characterizing the system 100, additional electrodes AA, BB, M, and N were added. However, these electrodes are not necessary for achieving the desired logical functions, as now discussed.

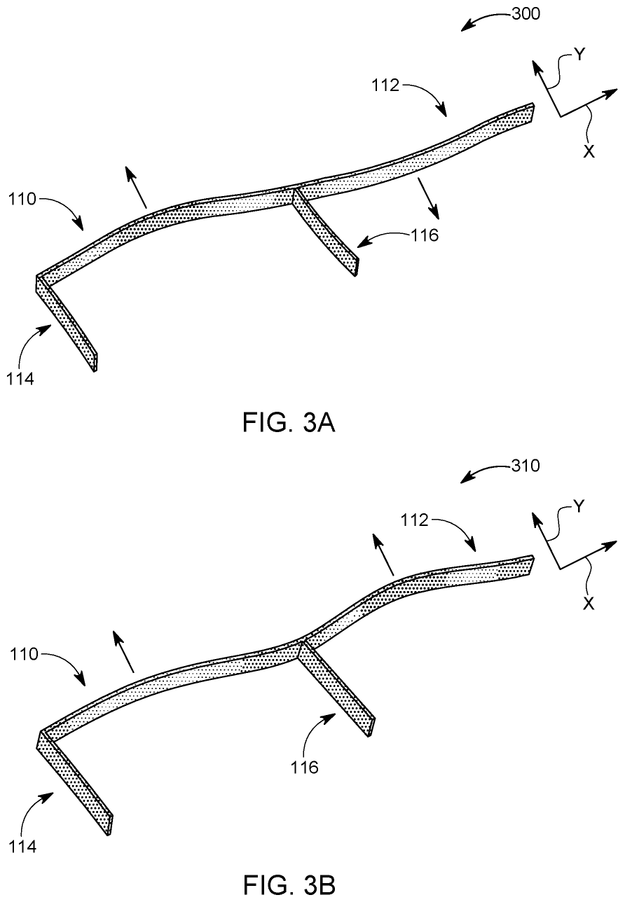

A finite element (FE) model was developed in COMSOL using the solid mechanic multiphysics to design and simulate the natural frequencies and vibrational mode shapes of the device 100. The FE simulations indicate that different distinct modes 300 and 310 can be excited from the F-shaped microstructure with no effect on each other, as shown in FIGS. 3A and 3B. Note that the first mode 300 has the first arch beam 110 bent along the positive direction of the Y axis while the second arch beam 112 is bent in the negative direction of the Y axis, i.e., they are out of phase, while the second mode 310 has both arch beams bent in the positive direction of the Y axis, i.e., they are in phase. The amount of bending is larger for the first arch beam than the second arch beam in FIG. 3A, and the amount of bending is larger for the second arch beam than the first arch beam in FIG. 3B.

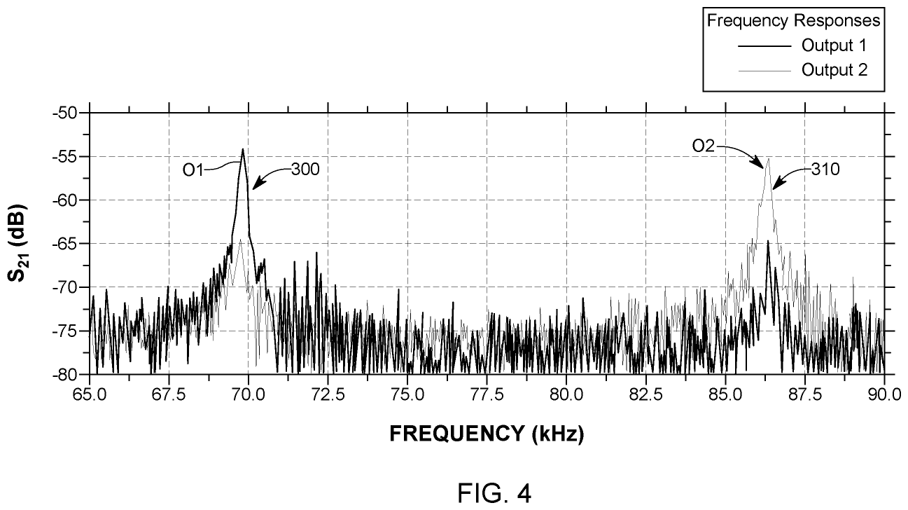

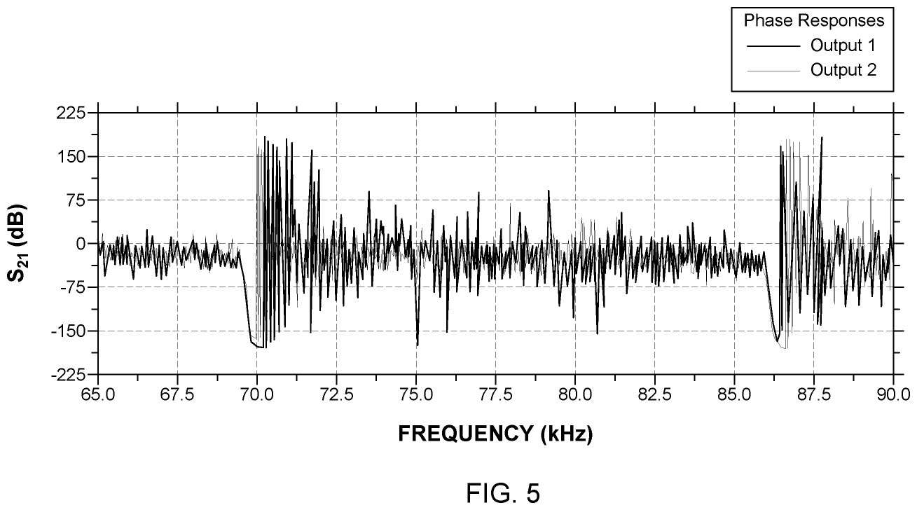

In periodic and compounded structures, the presence of a coupling point 113 or non-symmetric nature of the compound structure can significantly affect the mode shapes and lead to the mode localization phenomenon. In this embodiment, the resonances are all linear. No buckling is involved and they do not require asymmetric structure to demonstrate the logic functions. The coupling point 113 between the first and second arch beams may be utilized to control their stiffness, which may lead to competing effects between the quadratic and cubic nonlinearities in the arch beams. Also note that the bistability of the arch beams are not used or related to the demonstration of the logic functions. The coupling point can be employed to control the resonances of the two vibrational modes such that the resonant frequencies can be veered near each other depending on the form of actuations or modulations. In this regard, FIG. 4 shows the frequency response and FIG. 5 shows the phase response of the first and second modes 300 and 310 for the two outputs O1 and O2 obtained experimentally from the F-shaped coupled resonators 106 shown in FIG. 1. FIG. 4 indicates that the two modes 300 and 310 are distinct and do not affect each other. The measurements for the system 100 show the activated and deactivated resonances for the first mode 300 as being 69.76 kHz and for the second mode 310 being 86.25 kHz, with their corresponding phases illustrated in FIG. 5. The phases are obtained when the electrostatic force is applied on electrodes M and N in FIG. 1. These figures indicate that there is a relative difference in amplitudes between the first and second vibrational modes 300 and 310, and depending on which electrode is actuated and sensed, both the first and second modes can be localized and delocalized. Hence, the concept of activation and deactivation of the first and second modes of the F-shaped resonator 106 can be used to demonstrate both the fundamental and complex logic functions.

The outputs O1 and O2 for the frequency response (shown in FIG. 4) are used for implementing complex logical functions next. The phase outputs shown in FIG. 5 may also be used for additional complex logical functions. However, for simplicity, only the frequency responses are used in the examples discussed next. The proposed system 100 is reconfigurable in such a way that it can be used to demonstrate different logic functions using the same concept of activation and deactivation of the first and second vibrational modes 300 and 310. This system demonstrates that is possible to implement plural logical functions with a single device, i.e., the half adder function, the AND gate function, and the XOR gate function using the same device. This same system 100 can be used to demonstrate logic functions that require multi-input/output lines such as demux and 3 bits parity checker. The steps and conditions to achieve other logic functions through cascadability require signal conditioning elements between the two resonators such that if one resonator is outputting an AND gate logical function to another resonator that needs the AND gate as one of its output to perform a demux logic function, the signals from the first resonator are conditioned and transferred to the second resonator. Note that the F-shaped coupled resonator cannot be used to implement all logic functions and achieving other logic functions depend on the number of electrodes that are used for actuation and detection of the signals, the size and thickness of the structure for effective transduction and also the conditions of the logic functions to be demonstrated.

The amplitude level of the two resonances is used to define the ON/OFF states of the device. By applying an electrostatic actuation on the driving electrodes 130 and/or 132, the resonance of the resonator is activated, and that defines the ON state for the logic outputs. However, by de-actuating the driving electrodes 130 and/or 132, the resonant frequency is deactivated, and that defines the OFF state for the logic outputs. The natural frequencies for the first and second modes of the F-shaped resonator system 100 are 69.76 kHz and 86.25 kHz, respectively. For the half adder capability, both resonant frequencies are selected as the operating frequencies since this logic function requires two output lines. On the other hand, since each of the AND and XOR logic gates requires only one logic output, the first resonant frequency of the F-shaped resonator 106 is selected as the operating frequency for the AND logic gate while the second resonant frequency is selected for the XOR logic gate.

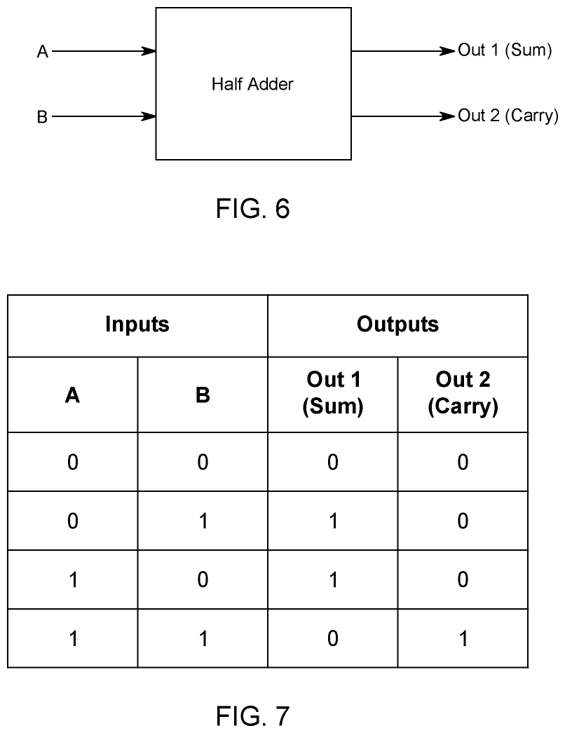

The half adder logic function is now discussed in more detail. The half adder is a combinational logic function that performs the addition of numbers from two binary digital inputs and provides two binary digital outputs (Sum and Carry bits). It requires two inputs (A and B) and two outputs (Sum (S) and Carry (C)) as schematically illustrated in FIG. 6. As shown in the schematic of FIG. 1, the two driving electrodes 130 and 132 are used as the two logic inputs A and B for activating and deactivating the resonances, and the two sensing electrodes 140 and 142 are used as the Sum and Carry bit outputs. When one of the driving electrodes 130 and 132 is actuated, both the first and second frequency modes 300 and 310 can be activated, but with different levels of amplitude due to the mode localization phenomenon. The mode with the higher vibrational energy and amplitude level will route its data line through the corresponding output electrode. However, the amplitude level of the other mode is smaller than the signal-to-noise ratio of the device such that the signal is buried in the noise and cannot be transferred to its output line.

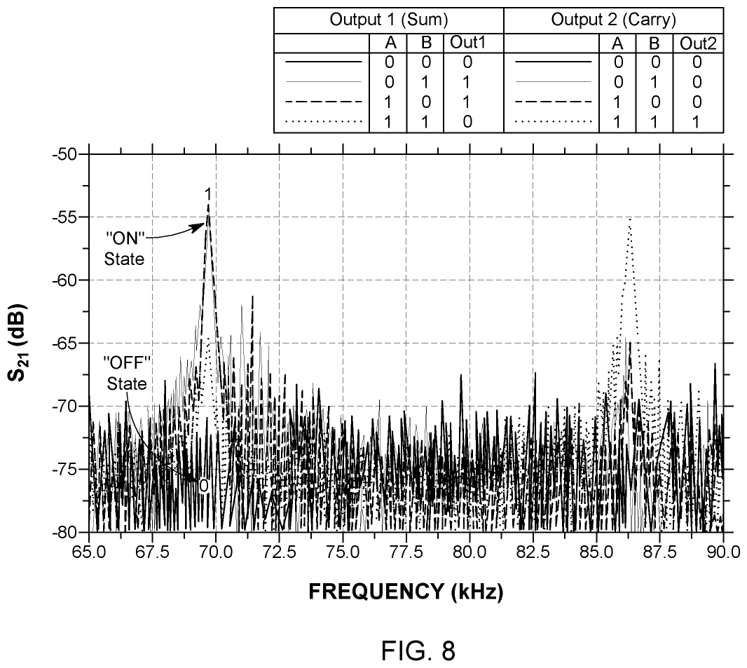

From the half adder truth table shown in FIG. 7, when only the input B is enabled, the resonance is activated in the first frequency mode 300, and thus, the Sum bit output O1 is in ON state. Likewise, when only input A is enabled, the resonance is still activated in the first frequency mode 300, and thus, the Sum bit output O1 is in ON state. However, when both inputs A and B are enabled, the second mode 310 is activated. Thus, the Carry bit output O2 is in ON state. However, the first mode 300 is deactivated, and its corresponding output is in the OFF state. FIG. 8 shows the S₂₁ transmission measurements for the output data lines O1 and O2.

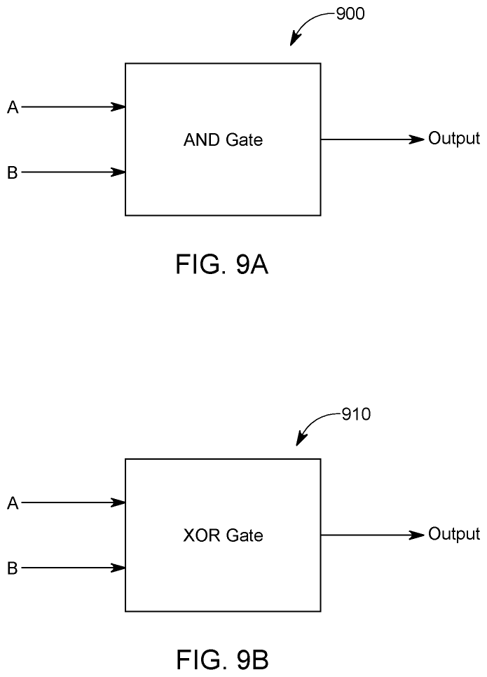

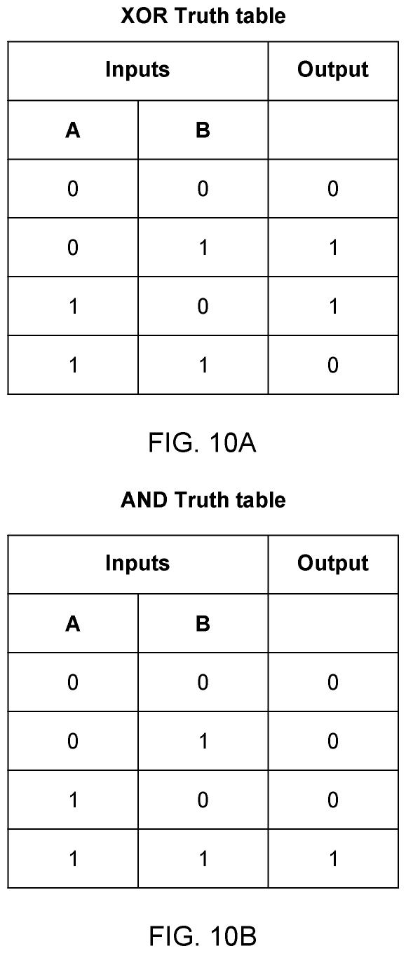

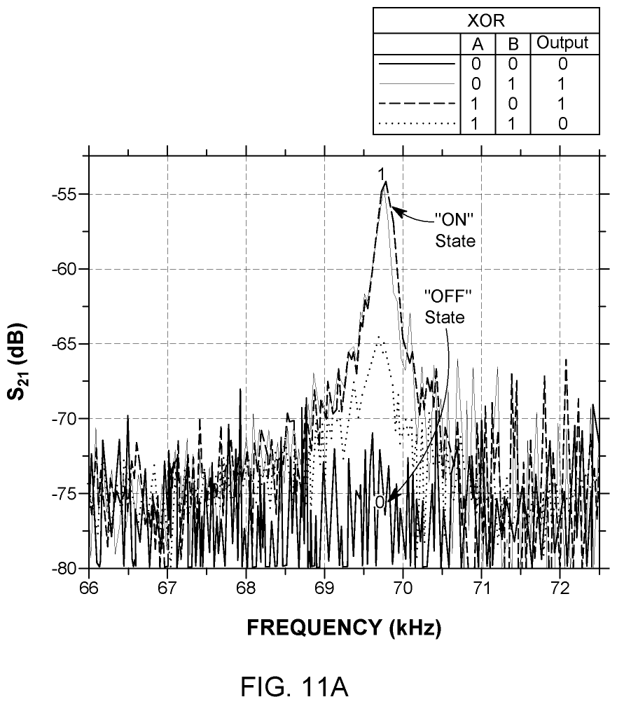

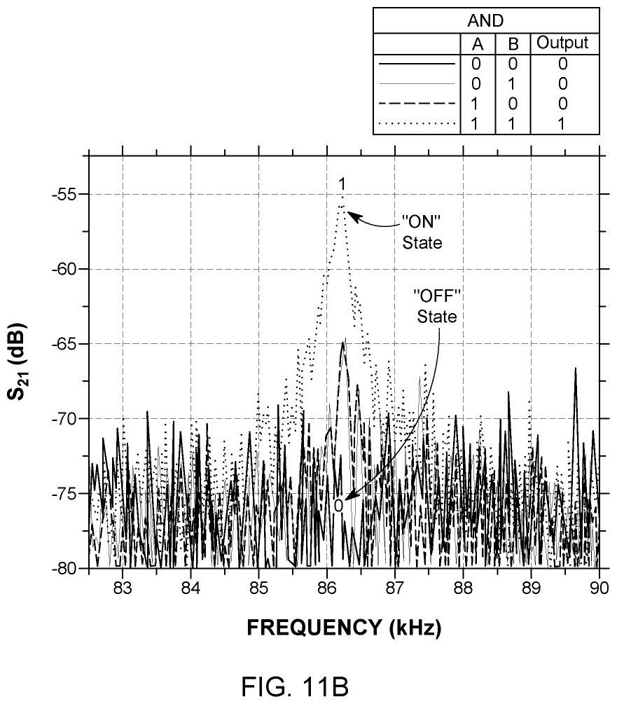

The XOR and AND logic gates may be implemented with the same system 100 as now discussed. Considering the fact that the half adder function discussed with regard to FIGS. 6-8 is built from two fundamental logic gates (AND and XOR gates), the run-time re-programmability of the MEMS resonator-based computing devices can be explored to demonstrate both AND and XOR logic gates for the same system 100. In these cases, each of the logic gates 900 and 910 requires two inputs A and B and one output line, as illustrated in FIGS. 9A and 9B, respectively. The frequency of the first mode 300 of the F-shaped resonator 106 is selected as the operating frequency for the XOR gate 910, and the frequency of the second mode 310 is selected for the AND logic gate 900. The truth tables and experimental frequency responses are shown in FIGS. 10A and 10B and FIGS. 11A and 11B, respectively. Note that FIGS. 11A and 11B show the large difference between the ON and OFF states for the same resonant frequency, which means that the system 100 can easily distinguish between these states. For the XOR gate 910, the vibrational energy of the resonator is activated in the first mode 300, when only input A or B is enabled, and thus, its output line is in ON state, while for the other input conditions, the output line is in the OFF state. However, the activation of both inputs A and B for the AND gate 900 confines the vibrational energy to the second frequency mode 310. Thus, the output line is in ON state. For this input condition, the first mode 300 is deactivated, and the mode toggling is more sensitive and dominant in the second frequency mode 310. However, the output line will be in OFF state for all other AND logic input conditions.

There are a couple of factors that might influence the behavior of the system 100, e.g., ambient temperature, shock robustness, etc. These factors and their influence on the system 100 are now discussed. The temperature fluctuation during the operation of MEMS resonators can affect the frequency stability, and this can distort logic operations. Frequency instability due to temperature fluctuation is a real concern for an electrothermally actuated MEMS resonator. The same is true when the frequency modulations for MEMS resonator-based logic devices are based on electrothermal switching. However, in the embodiments discussed herein, the F-shaped resonators 106 are neither electrothermally actuated nor requires frequency modulation. On the other hand, the MEMS resonator system 100 should be able to maintain a stable operating frequency under long term operation or different environmental conditions such as a wide range of temperatures.

MEMS resonator-based computing devices will successfully perform their operations as long as the frequency fluctuation is within the bandwidth of the resonator. The frequency fluctuation due to temperature changes can be evaluated according to the formula f(T)=f₀[1+TC_{f}(T−T₀)], where f₀ is the resonant frequency, TC_{f}=−25 ppm/° C. is the temperature coefficient of the resonant frequency, T₀=25° C., and f(T) is the resonant frequency at temperature T, which is assumed to be between −25 and 100° C. The range of frequency fluctuations for both output one O1 and output two O2 within the assumed temperature range are evaluated to be ±109 Hz and +134.77 Hz, respectively, and they are within the bandwidths of both outputs 220 Hz and 250 Hz, respectively. Hence, the F-shaped resonators 106 can perform the desired logic operations in the assumed range of temperature variations.

Another factor to be considered for MEMS resonator-based logic devices is the shock robustness. The MEMS resonator can be exposed to shock during fabrication, operation, or packaging, and this can result in unexpected failure because of the pull-in instability or broken microstructures due to the mechanical shock. The shock survivability of the F-shaped resonator system 100 is estimated to be in the range of 40,000 g to 70,000 g. The F-shaped resonators 106 show a high shock robustness because of uniform stress distribution in its geometry, and there is no stress concentration in any part.

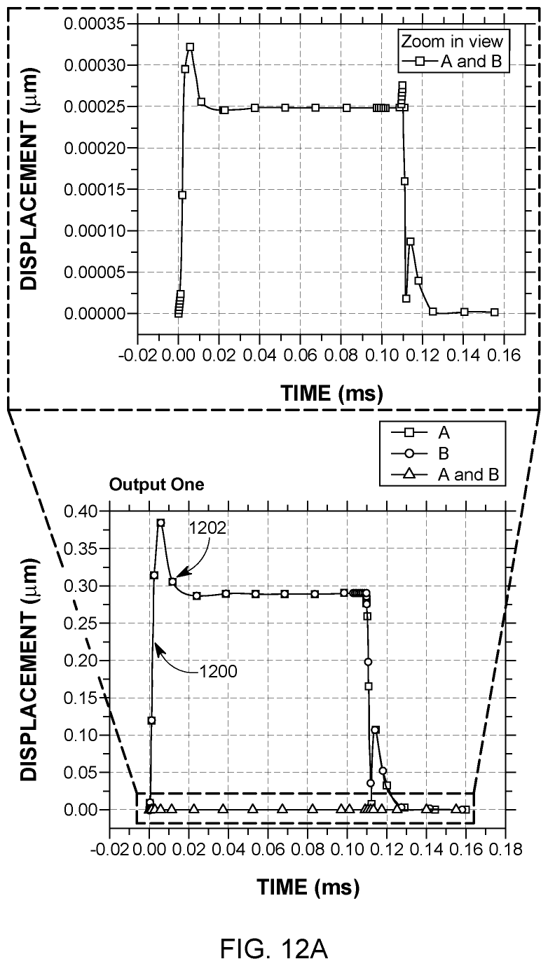

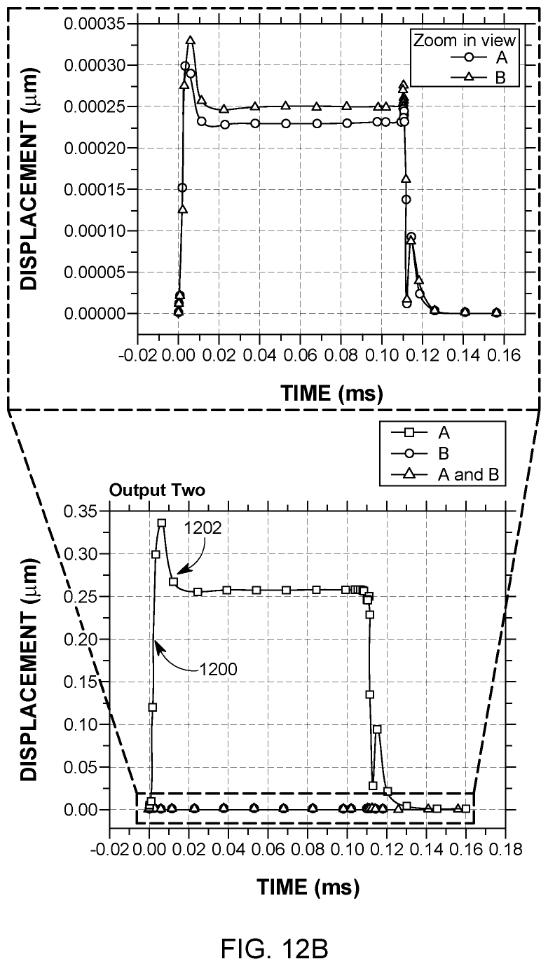

The switching speed of the system 100 can be estimated from the f/Q ratio, where f is the operating frequency (69.76 Hz and 86.25 kHz for output one O1 and output two O2, respectively), and Q is the quality factor, which is measured to be 317.09 and 345 for output one and output two, respectively. Thus, the switching speed is estimated to be 220 Hz for output one and 250 Hz for output two, and these correspond to a switching time of 4.54 ms and 4.00 ms, respectively. Also, because the proposed algorithm for system 100 is based on activation and deactivation of the modes, it is necessary to evaluate the time it takes the outputs of the device to respond to the inputs. The response time and speed give measures on how quick the F-shaped resonators 106 react to inputs. The response time and speed of the F-shaped resonators 106 can be estimated through FE simulations by using the time-dependent study in the COMSOL MEMS module. The F-shaped resonator system 100 is subjected to rectangular step inputs to determine the transition responses for both outputs from OFF state to ON state vice versa, and the time it takes the responses to reach steady states during activation and deactivation. As illustrated in FIGS. 12A and 12B, the responses show a very short rise time 1200, with overshoot 1202 during the transient state for all the “ON” and “OFF” logic input conditions. The time responses reach steady-state conditions around 0.05 ms for both high and low states, which indicates the settling time and how fast the system response to the inputs. Hence, the response time is around 0.05 ms, and the corresponding response speed is about 20 kHz. Though MEMS resonator-based computations are limited by the operating speed and high performance in comparison with CMOS technology, power consumptions are more important than speed in some applications such as IoT and smart devices, and thus, the MEMS resonator-based device are more advantageous than the traditional transistor-based devices as their power consumer is much lower.

Another factor to be considered for the MEMS resonator-based systems is the total energy cost per logic operation, which is evaluated by summing all the energies that contribute to the logic operations. It consists of the switching energy due to the frequency modulations and the actuation energy for driving or activating the micro-resonator system. The switching energy is a result of the additional applied DC voltages for the frequency modulations, and this consumes a considerable amount of energy. On the other hand, the proposed approach in the embodiments discussed herein uses only the actuation energy because there is no frequency modulation, and the switching energy does not contribute to the total energy. Thus, the total energies are estimated to be 14.357 pJ and 12.65 pJ for output one and output two, respectively.

Another approach is to evaluate the actuation energy by simulation using the MEMS module from COMSOL commercial software. The average actuation energy per logic operation is obtained from the electromechanics model to be 1.5 nW and 1.31 nW for output one and output two, respectively. These values are relatively smaller than the analytical calculations because COMSOL accurately estimates the changes in the capacitance and impedance with respect to the combinations of all the logic inputs instead of relying on the parallel plate assumption as in the analytical calculations. In addition, the analytical calculations are formulated for simple microstructures but not for coupled microstructures. The power consumption can be compared with other existing technologies to be 4.49 nW and 5.909 nW respectively. It can be deduced from the obtained actuation energy that the proposed system, based on activation/deactivation, is energy efficient, and it is appropriate for the new generation of MEMS resonator-based logic devices. It should be noted that there could be a further decrease in the actuation energy by optimizing the dimensions of the present device to be in the nanoscale range.

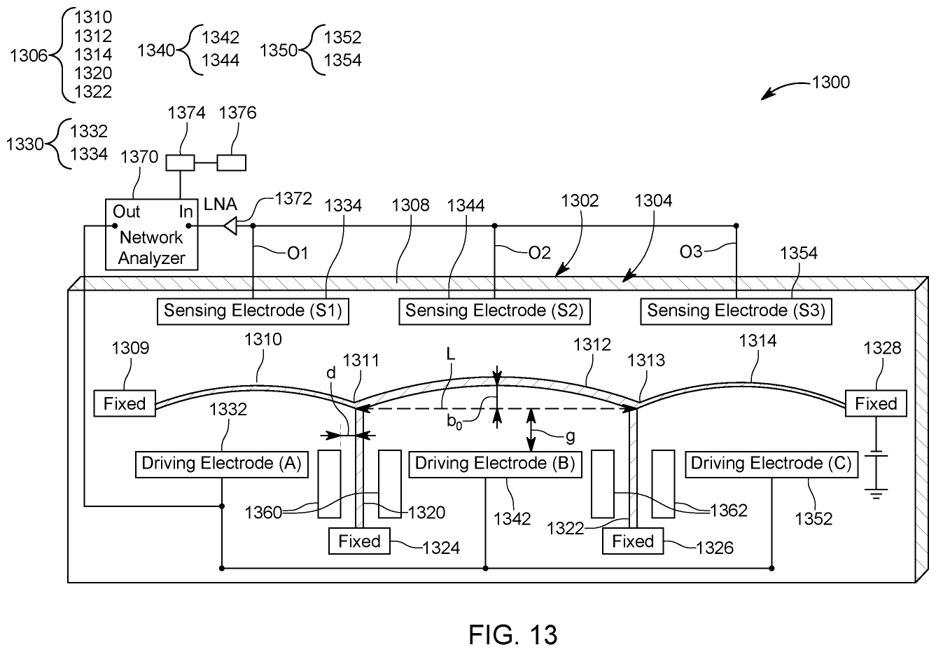

According to another embodiment, which is illustrated in FIG. 13, a different coupled microstructure system 1300 is proposed, and this new system also has the ability to provide multi-inputs/outputs logic functions. The system 1300 includes a coupled structure 1306 that includes, in-plane connected microbeams in the form of a fork shape with three arch beams and two straight side beams. More specifically, the coupled structure 1306 includes a first arch beam 1310, a second arch beam 1312, and a third arch beam 1314, connected in series to each other, i.e., a first end of the first arch beam 1310 is anchored at point 1309 to the substrate and the second end is connected to a first end of the second arch beam, at a point/joint 1311. The second end of the second arch beam 1312 is connected to a first end of the third arch beam 1314, at a point/joint 1313. The second end of the third arch beam is fixed to an anchor 1328. The first straight beam 1320 has one end connected to point 1311 and the other end is fixed at an anchor 1324. The second straight beam 1322 is connected with one end to point 1313 and with the other end to anchor 1326. Note that the anchors are grounded and that points/joints 1311 and 1313 are floating above the substrate 1312 and thus, the straight beams can deflect when the driving electrodes apply a desired voltage. Similar to the F-shaped microstructure 106, the two straight side beams 1320 and 1322 are connected to the arch beam joints and their tips can be used to control and guide the motions of the arch beams such that when one arch beam is subjected to a tensile axial force, the other connected arch beam would be subjected to a compressive axial force.

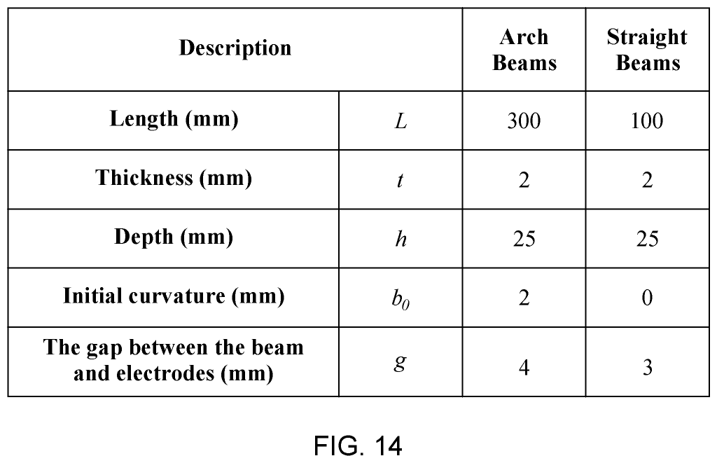

In one embodiment, the center arch beam 1312 is thicker than the other arch beams 1310 and 1314 so that it can be used to suppress the activation of some vibrational modes and in addition, it would increase the stiffness of the coupled microstructure 1306 at the center, such that it may reveal different nonlinear dynamic phenomena, which can result from the competing effects between the quadratic and cubic nonlinearities of the arch beams. One or more of the straight and arch beams may be sandwiched between pairs of electrodes that serve as upper and lower electrodes for the straight and/or arch beams, and these electrodes can be used for electrostatic actuation and sensing of the device. For example, FIG. 13 shows a first pair 1330 of a driving electrode 1332 and a sensing electrode 1334 located around the first arch electrode 1310, a second pair 1340 of a driving electrode 1342 and a sensing electrode 1344 located around the second arch electrode 1312, and a third pair 1350 of a driving electrode 1352 and a sensing electrode 1354 located around the third arch electrode 1314. Note that in one implementation, the driving electrodes may be located on the substrate 1302, under the corresponding arch beams, while the sensing electrodes may be located above the corresponding arch beams. In one application, all the electrodes are located on the substrate 1302. Although FIG. 13 also shows pairs of electrodes 1360 and 1362 around the straight beams 1320 and 1322, respectively, these electrodes are optional in this embodiment. Note that any of the lower electrodes can be used to electrostatically or electrothermally excite the vibrational modes of the resonator, i.e., any of the lower electrodes can be used as the driving electrodes. The outputs O1 to O3 can be sensed from any of the upper electrodes 1334, 1344, or 1354. FIG. 14 shows the dimensions of the arch and straight beams for the embodiment illustrated in FIG. 13. Those skilled in the art, having the hindsight of this disclosure, would understand that by varying one or more of these dimensions by 30% would still achieve the desired functionality.

Similar to the system shown in FIG. 1, the system 1300 may include a network analyzer 1370 and an LNA 1372. A controller 1374 may be connected to the network analyzer to control the type of signal being applied to the driving electrodes, which driving electrode to be activated, an amplitude of the signal, a timing of applying the signal, and also for analyzing the sensed signal. A power supply 1376 may also be provided to the system 1300 to supply the electrical power necessary for generating the signals and processing them.

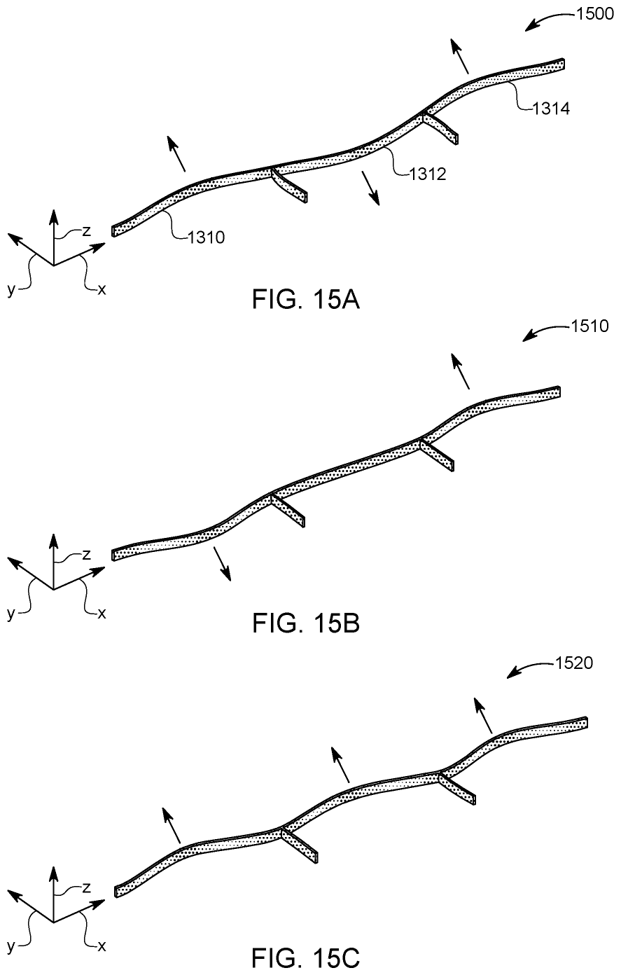

A finite element (FE) model was developed in COMSOL using the solid mechanic multiphysics to design and simulate the natural frequencies and vibrational mode-shapes of the system shown in FIG. 13. Note that the axial load is not included in the simulations and the first three natural frequencies are obtained to be 108.5 kHz, 118.52 kHz and 180.9 kHz respectively. The simulations from the finite elements are shown in FIGS. 15A to 15C, and they indicate a confinement of the vibrational energy between the distinct localized modes 1500, 1510, and 1520 of the individual arch beams. It can be observed that the first vibrational mode 1500 is localized and dominant for all the arch beams, which are out-of-phase with each other. The second mode 1510's shape indicates that the mode cannot be sensed from the center arch beam 1312 because it is thicker than the other arch beam and therefore, the vibrational energy of the second mode is suppressed for the center arch beam. Only the first and third arch beams are exhibiting vibrational energy, and these two arch beams oscillate out-of-phase. The vibrational energy of the third mode 1520 is dominant and localized in all the arch beams and in this case, the arch beams are in-phase mode. This indicates that the sensitivity of each mode depends on the actuating and sensing electrodes.

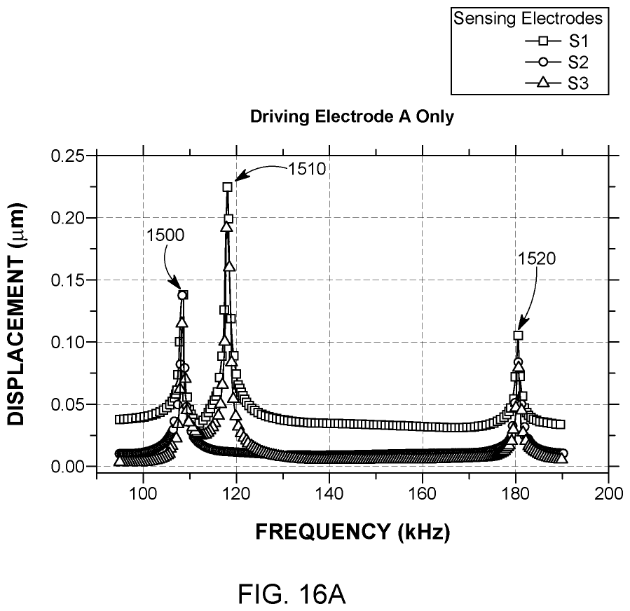

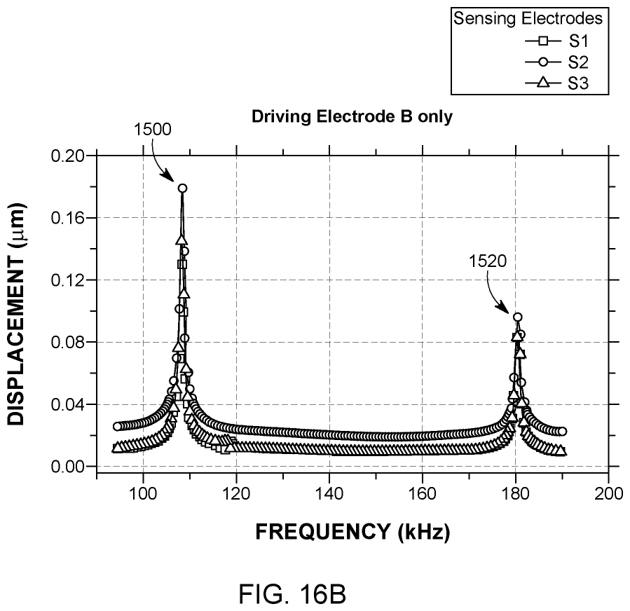

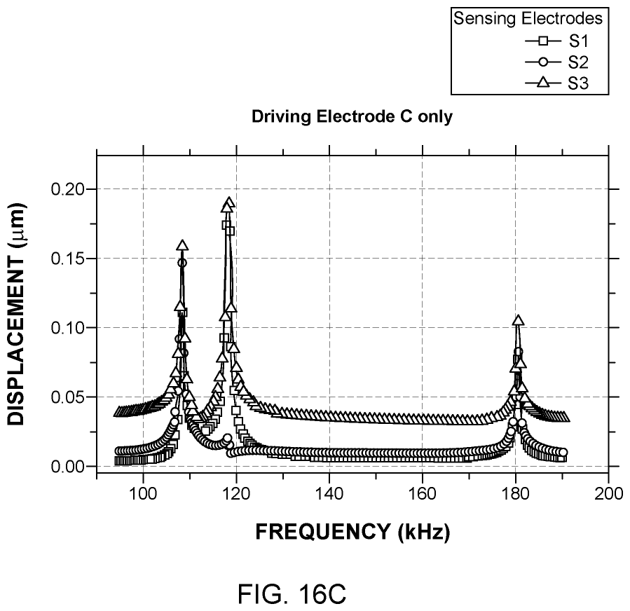

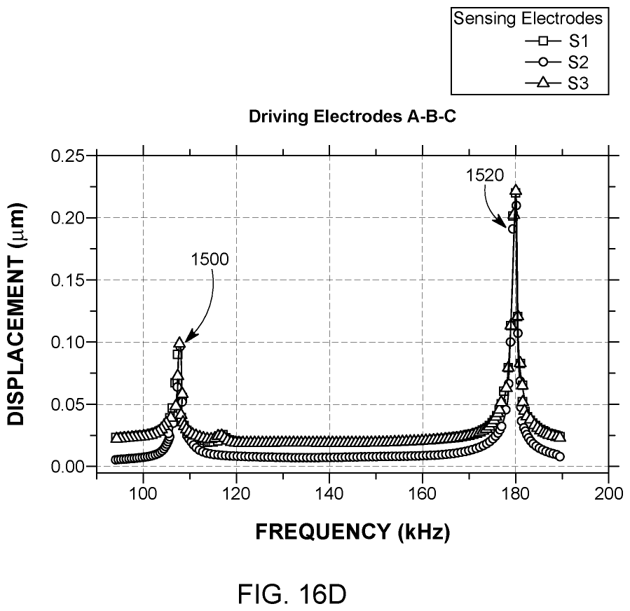

The energy confinement and the optimal sensitivity of the vibrational amplitude for the responses of the system 1300 strongly depends on the choice of the actuating and sensing electrodes. The localization of the vibrational energy for the first three vibrational modes of the fork-shaped coupled microbeams structure 1306 is studied numerically considering the actuations of different electrodes configurations. For the numerical simulations, the electrostatic actuation is based on a DC load of 20V, which is superimposed over an AC harmonic load of 0.1V. Note that the AC load is kept at 0.1V to avoid nonlinear effects due to the electrostatic force, for the purpose of this embodiment in which parallel logics is desired. FIGS. 16A to 16D show the results from the numerical simulations with the frequency responses for the first mode 1500, second mode 1510, and third mode 1520 to be around 108.5 kHz, 118.52 kHz and 180.9 kHz respectively. When the coupled structure 1306 is actuated from only driving electrode 1332 and sensed from all the sensing electrodes S1, S2 and S3, FIG. 16A indicates the relative difference in the amplitude of the frequency responses. It can be observed in FIG. 16A that the second mode 1510 is not activated when sensing from S2. However, the vibrational energy is confined in the second resonance mode and makes it dominant when sensing from S1 and S3. Sensing from S1, which is close to the region of actuation, does not give highest amplitude response to the first mode even though the first mode should have been dominant.

In the case of actuating the coupled structure 1306 only from the driving electrode 1342, it can be noted from FIG. 16B that the energy distribution of the coupled system is confined and localized in the first resonance mode 1500 when sensing from all the sensing electrodes and the second mode 1510 is suppressed from all the sensing electrodes. Actuating the structure 1306 only from the driving electrode 1352 produces roughly the same responses like when driving only from electrode 1332 due to the geometrical symmetry of the coupled structure as shown in FIG. 16C. However, when all the driving electrodes (1332, 1342 and 1352) are actuated altogether, the vibrational energy is confined in the third resonance mode 1520 when sensing from all the sensing electrodes, as shown in FIG. 16D, and in this case, the second mode 1510 is not activated when sensing from S2 while it is suppressed when sensing from S1 and S3.

The MEMS resonator-based logic systems discussed here constitute a platform, which allows the cascadability of energy-efficient MEMS resonators for complex logic functions. The above embodiments show energy-efficient complex logic function (half-adder) and basic logic gates (XOR and AND gates) using vibration modes activation and deactivation. The proposed approach enables the systems 100 or 1300 to consume energy in femtojoules per logic operations. The concept implemented in the system 100 is based on activating and deactivating the first and second vibration modes of an F-shape coupled resonator. The mode switching was used to induce the activation and deactivation of the vibration modes such that the system can be used for multi-inputs and multi-outputs logic functions. The input and output signals from the systems discussed herein are AC-based signals, which are actuated and sensed at the same frequency. This feature of the discussed embodiments enable cascadability, significant energy improvement, and gives a prospect to perform more complex computing operations.

The structures discussed herein can be used for multi-inputs/outputs logic functions and in addition, these structures offer various possibilities to control the stiffness of the arch beams, and hence, leads to various possible logic outputs. This enables programmability of the system to give different multifunctional logic functions depending on the combination of the driving and sensing electrodes. Thus, with a single frame microstructure 100 or 1300, different complex logic operations can be obtained simultaneously from the plural outputs to demonstrate parallel logics.

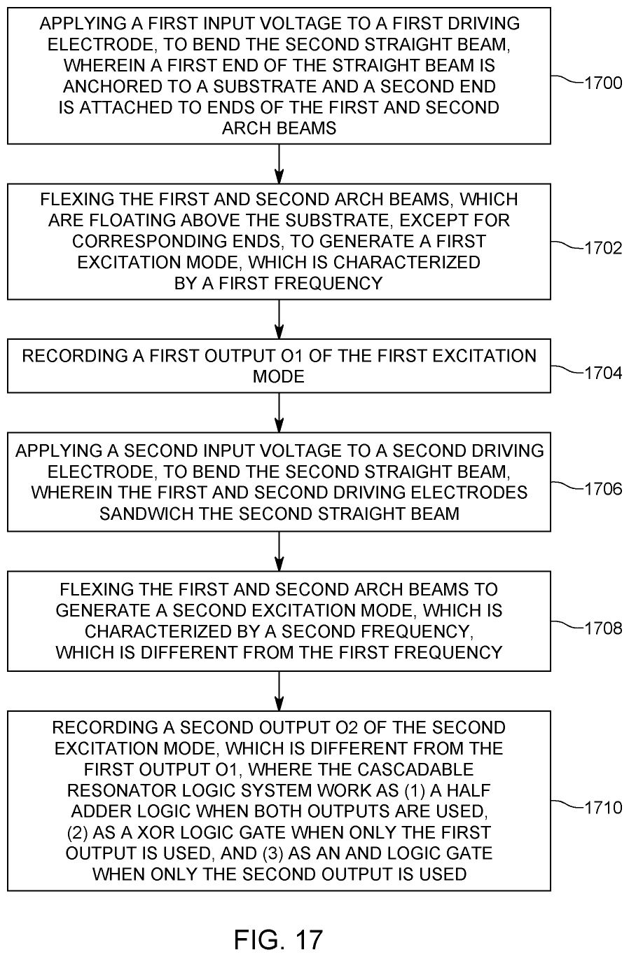

A method for performing calculations with the system 100 or 1300 is now discussed with regard to FIG. 17. The method includes a step 1700 of applying a first input voltage to a first driving electrode, to bend the second straight beam, wherein a first end of the straight beam is anchored to a substrate and a second end is attached to ends of the first and second arch beams, a step 1702 of flexing the first and second arch beams, which are floating above the substrate, except for corresponding ends, to generate a first excitation mode, which is characterized by a first frequency, a step 1704 of recording a first output O1 of the first excitation mode, a step 1706 of applying a second input voltage to a second driving electrode, to bend the second straight beam, wherein the first and second driving electrodes sandwich the second straight beam, a step 1708 of flexing the first and second arch beams to generate a second excitation mode, which is characterized by a second frequency, which is different from the first frequency, and a step 1710 of recording a second output O2 of the second excitation mode, which is different from the first output O1, where the cascadable resonator logic system works as (1) a half adder logic when both outputs are used, (2) as a XOR logic gate when only the first output is used, and (3) as an AND logic gate when only the second output is used.

In one application, the first and second input voltages and the first and second outputs are AC signals having a same frequency. The first and second arch beams are flexed out of phase for the first excitation mode and in phase for the second excitation mode. The method may further include, when used with the system 1300, applying a third input voltage to a third driving electrode, flexing the first and second arch beams and an additional third arch beam, to generate a third excitation mode, which is characterized by a third frequency, and recording a third output of the third excitation mode.

The disclosed embodiments provide a multi-inputs/outputs MEMS based system for performing plural logical functions. It should be understood that this description is not intended to limit the invention. On the contrary, the embodiments are intended to cover alternatives, modifications and equivalents, which are included in the spirit and scope of the invention as defined by the appended claims. Further, in the detailed description of the embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

### REFERENCES

The entire content of all the publications listed herein is incorporated by reference in this patent application.
[1] Hafiz, M. A. A., Kosuru, L., and Younis, M. I., 2016, “Microelectromechanical Reprogrammable Logic Device,” Nat. Commun., 7(1), p. 11137.
[2] Tella, S. A., and Younis, M. I., 2019, “Multimode Excitations for Complex MultifunctionalLogic Device,” J. Micromechanics Microengineering, 29(12), p. 125017.
[3] Hafiz, M. A. A., Tella, S., Alcheikh, N., Fariborzi, H., and Younis, M. I., 2017, “Axially Modulated Clamped-Guided Arch Resonator for Memory and Logic Applications,” Volume 4: 22nd Design for Manufacturing and the Life Cycle Conference; 11th International Conference on Micro- and Nanosystems, American Society of Mechanical Engineers, Cleveland, Ohio, USA, p. V004T09A016.
[4] Chu, C.-H., Shih, W.-P., Chung, S.-Y., Tsai, H.-C., Shing, T.-K., and Chang, P.-Z., 2007, “A Low Actuation Voltage Electrostatic Actuator for RF MEMS Switch Applications,” J. Micromechanics Microengineering, 17(8), pp. 1649-1656.
[5] Hafiz, M. A. A., Tella, S., Alcheikh, N., Fariborzi, H., and Younis, M. I., 2018, “Axially Modulated Arch Resonator for Logic and Memory Applications,” Mechatronics, 56, pp. 254-260.
[6] Yao, A., and Hikihara, T., 2014, “Logic-Memory Device of a Mechanical Resonator,” Appl. Phys. Lett., 105(12), p. 123104.
[7] Ilyas, S., Ahmed, S., Hafiz, M. A. A., Fariborzi, H., and Younis, M. I., 2019, “Cascadable Microelectromechanical Resonator Logic Gate,” J. Micromechanics Microengineering, 29(1), p. 015007.
[8] Younis, M. I., 2011, MEMS Linear and Nonlinear Statics and Dynamics, Springer US, Boston, Mass.

What is claimed is:

1. A cascadable resonator logic system comprising:
a substrate;
a first straight beam anchored with a first end to the substrate;
a second straight beam anchored with a first end to the substrate;
a first arch beam, which is curved, and is attached with a first end to a second end of the first straight beam, at a first joint, and with a second end to a second end of the second straight beam, at a second joint, so that both the first and second ends of the first arch beam are suspended above the substrate; and
a second arch beam, which is also curved, and is attached with a first end to the second joint, and a second end is anchored to the substrate.

2. The system of claim 1, wherein the entire first arch beam is suspended above the substrate.

3. The system of claim 1, further comprising:
a first anchor configured to attach the first end of the first straight beam to the substrate;
a second anchor configured to attach the first end of the second straight beam to the substrate; and
a third anchor configured to attach the second end of the second arch beam to the substrate.

4. The system of claim 3, wherein there is no other anchor connecting to any of the first and second straight beams and the first and second arch beams.

5. The system of claim 1, wherein each of the first and second straight beams and each of the first and second arch beams extend in a plane parallel to the substrate.

6. The system of claim 1, wherein at least one dimension of each of the first and second straight beams and the first and second arch beams is in the micro-meter range.

7. The system of claim 1, wherein all dimensions of each of the first and second straight beams and the first and second arch beams are in the micro-meter range.

8. The system of claim 1, further comprising:
first and second driving electrode sandwiching the second straight beam, the first and second driving electrodes configured to apply a corresponding voltage to the second straight beam to displace the second straight beam and to flex the first and second arch beams.

9. The system of claim 8, further comprising:
first and second sensing electrodes placed next to the first and second arch beams, respectively, for sensing a response of the first and second arch beams when the second straight beam is displaced.

10. The system of claim 9, wherein the first and second driving electrodes apply first and second inputs, respectively, and the first and second sensing electrodes measure first and second outputs, respectively.

11. The system of claim 10, further comprising:
a processing device configured to generate the first and second inputs, and to collect the first and second outputs,
wherein the first and second outputs correspond to one of a half adder logic function, an XOR gate logic, and an AND gate logic.

12. The system of claim 8, wherein a voltage applied by either the first driving electrode or by the second driving electrode generates a first mode in the first and second arch beams, and another voltage applied simultaneously by the first and second driving electrodes generates a second mode in the first and second arch electrodes, which is characterized by a frequency different from a frequency of the first mode.

13. The system of claim 1, wherein the first and second straight beams and the first and second arch beams are located inside a vacuumed enclosure, located on the substrate.

14. The system of claim 1, further comprising:
a third arch beam, which is curved, and connected with a first end to the first straight beam and to the first arch beam, at the first joint, and connected with a second end to an anchor attached to the substrate.

15. The system of claim 14, further comprising:
pairs of a driving electrode and a sensing electrode, each pair corresponding to an arch beam of the first to third arch beams, and each pair sandwiching the corresponding arch beam.

16. The system of claim 15, wherein there are three different input voltages applied by the driving electrodes to generate three different modes in the first to third arch beams.

17. A method for performing a logical operation with a cascadable resonator logic system that includes first and second straight beams and first and second arch beams, the method comprising:
applying a first input voltage to a first driving electrode, to bend the second straight beam, wherein a first end of the straight beam is anchored to a substrate and a second end is attached to ends of the first and second arch beams;
flexing the first and second arch beams, which are floating above the substrate, except for an end of the second arch beam, to generate a first excitation mode, which is characterized by a first frequency;
recording a first output (O1) of the first excitation mode;
applying a second input voltage to a second driving electrode, to bend the second straight beam, wherein the first and second driving electrodes sandwich the second straight beam;
flexing the first and second arch beams to generate a second excitation mode, which is characterized by a second frequency, which is different from the first frequency; and
recording a second output (O2) of the second excitation mode, which is different from the first output (O1),
wherein the cascadable resonator logic system works as (1) a half adder logic when both outputs are used, (2) as a XOR logic gate when only the first output is used, and (3) as an AND logic gate when only the second output is used.

18. The method of claim 17, wherein the first and second input voltages and the first and second outputs are AC signals having a same frequency.

19. The method of claim 17, wherein the first and second arch beams are flexed out of phase for the first excitation mode and in phase for the second excitation mode.

20. The method of claim 17, further comprising:
applying a third input voltage to a third driving electrode;
flexing the first and second arch beams and an additional third arch beam, to generate a third excitation mode, which is characterized by a third frequency; and
recording a third output of the third excitation mode.
